(19) United States
(12) Patent Application Publication
(10) Pub. No.: US 2026/0082859 A1
(43) Pub. Date: Mar. 19, 2026

(54) SCANNING HOLOGRAPHY-BASED SUBSTRATE ALIGNMENT APPARATUS AND METHOD

(71) Applicant: CUBIXEL CO., LTD., Gwangjin-gu, Seoul (KR)

(72) Inventors: Taegeun KIM, Seoul (KR); Youseok KIM, Seoul (KR); Heekyung SUNG, Seongnam-si Gyeonggido (KR)

(73) Assignee: CUBIXEL CO., LTD., Gwangjin-gu, Seoul (KR)

(21) Appl. No.: 19/122,499

(22) PCT Filed: Jul. 12, 2023
(86) PCT No.: PCT/KR2023/009912

§ 371 Date: Apr. 18, 2025

(30) Foreign Application Priority Data
Nov. 14, 2022 (KR) 10-2022-0151775

(51) Int. Cl. H01L 21/68; G03H 1/22; H01L 21/67

(52) U.S. Cl. CPC H10P 72/53; G03H 1/2202; H10P 72/0606; H10P 72/0618

(57) ABSTRACT

The present disclosure relates to a scanning holography-based substrate alignment apparatus and method, wherein the apparatus includes: a sample fixing unit including a plurality of holders configured to support substrates at different positions by fixing each of the substrates at both ends thereof, each of the substrates including a substrate and a chip; a sample transfer unit configured to move the substrates at the different positions supported by the plurality of holders to a specific position; a holographic information receiving unit configured to receive holographic information about the substrates at the different positions from a holographic optical apparatus; a substrate position determination unit configured to analyze the holographic information through a holographic signal processing apparatus to determine position information for the substrates at the different positions; and a substrate position re-aligning unit configured to re-align the substrates at the different positions using the position information.

### TECHNICAL FIELD

The present disclosure relates to a technique for aligning substrates at different positions, and more particularly, to an apparatus and method for precisely aligning different substrates using scanning holography that employs infrared, visible, or ultraviolet wavelengths.

### BACKGROUND ART

In recent years, in various technological fields, the technology to accurately align two substrates has become very important. Since the alignment between the substrates is performed at the final stage in a process or is an essential process for subsequent processes, if the two substrates are misaligned, the entire process may fail or subsequent processes may not be performed, resulting in significant damage.

There are currently various methods for aligning substrates, and one of the major methods is one that relatively measures the positional difference between a substrate and a substrate holder, rather than directly measuring the alignment status of the substrate. However, this method has a limitation of indirect measurement when performing fine alignment.

In addition, there may be a limitation when performing precise alignment if there is a slight movement of the substrate during a substrate transfer process after measuring the position between the substrate and a substrate holder.

### PRIOR ART DOCUMENT

### Patent Document

Korean Patent Application Publication No. 10-2020-0091814 (Jul. 31, 2020)

### DETAILED DESCRIPTION OF INVENTION

### Technical Problems

According to one embodiment of the present disclosure, the present disclosure provides a scanning holography-based substrate alignment apparatus and method, capable of precisely aligning different substrates using scanning holography that employs infrared, visible, or ultraviolet wavelengths.

### Technical Solution

Among the embodiments, a scanning holography-based substrate alignment apparatus includes: a sample fixing unit including a plurality of holders configured to support substrates at different positions by fixing each of the substrates at both ends thereof, each of the substrates including a substrate and a chip; a sample transfer unit configured to move the substrates at the different positions supported by the plurality of holders to a specific position; a holographic information receiving unit configured to receive holographic information about the substrates at the different positions from a holographic optical apparatus; a substrate position determination unit configured to analyze the holographic information through a holographic signal processing apparatus to determine position information for the substrates at the different positions; and a substrate position re-aligning unit configured to re-align the substrates at the different positions using the position information.

The holographic optical apparatus may include: a light source unit using any one of infrared, visible, and ultraviolet wavelengths; a scan beam generation unit configured to branch light of a specific wavelength to generate a scan beam through interference; a scanning unit capable of scanning an object; and a light detection unit configured to convert light reflected or transmitted from the target object into an electrical signal, and the holographic optical apparatus may be implemented to obtain a complex hologram of the target object.

The sample fixing unit may be implemented in a structure in which the plurality of holders are arranged vertically side by side, so that the substrates are arranged vertically side by side.

The holographic information receiving unit may obtain single integrated holographic information about at least one alignment mark displayed on an upper or lower surface of each of the substrates at the different positions.

The substrate position determining unit may reconstruct the alignment marks of the respective substrates at the different positions based on the single integrated holographic information to generate independent reconstructed images for the alignment marks of the respective substrates.

The substrate position determining unit may determine position coordinates for the alignment marks of the respective substrates at the different positions based on the respective reconstructed images.

The substrate position re-aligning unit may calculate a difference between the position coordinates of each of the alignment marks and re-aligns the substrates at the different positions based on the difference.

Among the embodiments, a scanning holography-based substrate alignment method includes: supporting, through a sample fixing member, substrates at different positions by fixing each of the substrates at both ends thereof using a plurality of holders, wherein each substrate includes a substrate and a chip; moving, through the sample transfer unit, the substrates at the different positions supported by the plurality of holders to a specific position; receiving, through a holographic information receiving unit, holographic information about the substrates at the different positions from a holographic optical apparatus; determining, through a substrate position determining unit, position information for the substrates at the different positions by analyzing the holographic information through a holographic signal processing apparatus; and re-aligning the substrates at the different positions using the position information through a substrate position re-aligning unit.

### Effect of Invention

The disclosed technology may have the following effects. However, the scope of the disclosed technology should not be construed as being limited thereby, because the specific embodiment is not necessarily required to include all of the following effects or only the following effects.

A scanning holography-based substrate alignment apparatus and method according to one embodiment of the present disclosure is capable of precisely aligning different substrates using scanning holography that employs infrared, visible, or ultraviolet wavelengths.

### BRIEF DESCRIPTION OF THE DRAWING

FIG. 1 is a drawing illustrating a substrate alignment system according to the present disclosure.

FIG. 2 is a drawing illustrating a holographic optical apparatus of FIG. 1.

FIG. 3 is a drawing illustrating an arrangement structure of substrates at different positions according to the present disclosure.

FIG. 4 is a drawing illustrating a functional configuration of the substrate alignment apparatus of FIG. 1.

FIG. 5 is a flowchart illustrating a substrate alignment method according to the present disclosure.

FIG. 6 is a flowchart illustrating one embodiment of a substrate alignment process according to the present disclosure.

FIG. 7 is a flowchart illustrating one embodiment of an overall process, including a substrate alignment process according to the present disclosure.

FIGS. 8 and 9 are drawings illustrating various embodiments of a transmissive structure of a holographic optical apparatus according to the present disclosure.

FIGS. 10 and 11 are drawings illustrating various embodiments of a reflective structure of a holographic optical apparatus according to the present disclosure.

### BEST MODE FOR CARRYING OUT THE INVENTION

The description of the present disclosure is merely for structural and functional illustration based on specific embodiments, and the scope of the invention should not be construed as being limited by the embodiments described herein. That is, since the embodiments may be variously changed and have various forms, the scope of the present disclosure should be understood to include equivalents capable of realizing the technical spirit of the present disclosure. Furthermore, the objects or effects presented in the present disclosure do not necessarily have to be entirely included in a specific embodiment or be the only effects included therein, and the scope of the present disclosure should not be construed as being limited thereby.

Meanwhile, meanings of terms described in the present application should be understood as follows.

The terms “first,” “second,” etc. are used to distinguish one component from other components, and the components are not limited by the terms. For example, a first component may be referred to as a second component without departing from the scope of the present disclosure, and likewise, a second component may be referred to as a first component.

It should be understood that, when it is described that a component is “connected to” another component, the component may be directly connected to another component or a third component may be present therebetween. In contrast, it should be understood that, when it is described that an element is “directly connected to” another element, it is understood that no element is present between the element and another element. Meanwhile, other expressions describing the relationship of the components, that is, expressions such as “between” and “directly between” or “adjacent to” and “directly adjacent to” should be similarly interpreted.

As used herein, the singular forms are intended to include the plural forms as well, unless the context clearly indicates otherwise. It will be further understood that the terms “comprises” or “have”, when used herein, specify the presence of stated features, integers, steps, operations, elements, and/or components, but do not preclude the presence or addition of one or more other features, integers, steps, operations, elements, components, and/or groups thereof.

In each step, reference numerals (e.g., a, b, c, etc.) are used for convenience of description, the reference numerals are not used to describe the order of the steps, and unless otherwise stated, it may occur differently from the order specified. That is, the respective steps may be performed similarly to the specified order, performed substantially simultaneously, and performed in an opposite order.

The present disclosure may be implemented as a computer-readable code on a computer-readable recording medium and the computer-readable recording medium includes all types of recording devices for storing data that may be read by a computer system. Examples of the computer readable recording medium include a ROM, a RAM, a CD-ROM, a magnetic tape, a floppy disk, an optical data storage device, and the like. Further, the computer readable recording media may be stored and executed as codes which may be distributed in the computer system connected via a network and read by a computer in a distribution method.

If it is not contrarily defined, all terms used herein have the same meanings as those generally understood by those skilled in the art. Terms which are defined in a generally used dictionary are interpreted to have the same meaning as the meaning in the context of the related art, and are not interpreted as an ideal meaning or excessively formal meanings unless clearly defined in the present application.

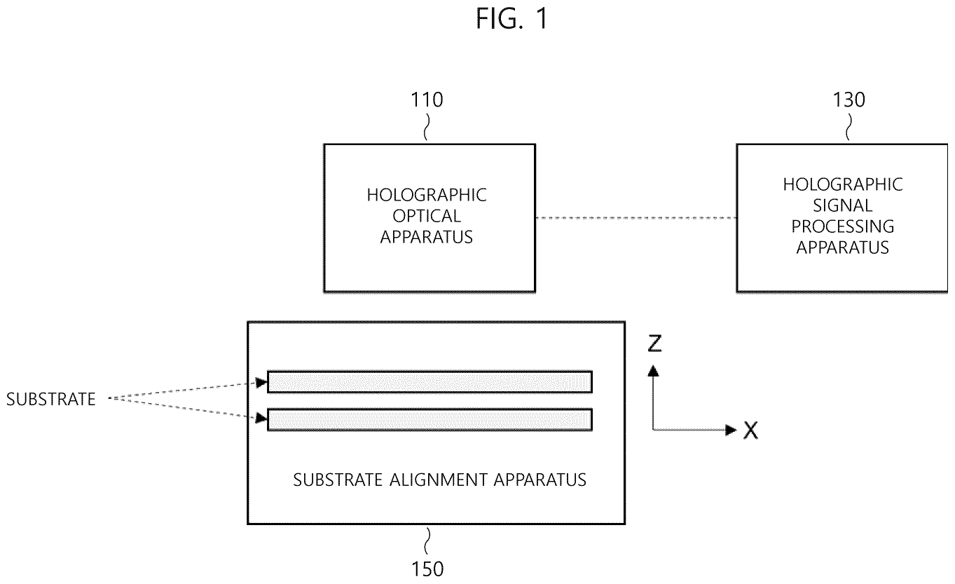

FIG. 1 is a drawing illustrating a substrate alignment system according to the present disclosure.

Referring to FIG. 1, a substrate alignment system 100 may include a holographic optical apparatus 110, a holographic signal processing apparatus 130, and a substrate alignment apparatus 150.

The holographic optical apparatus 110 may correspond to an apparatus that collects holographic information about a substrate supported by the substrate alignment apparatus 150. The holographic signal processing apparatus 130 may correspond to an apparatus that receives and analyzes holographic information collected by the holographic optical apparatus 110. The holographic signal processing apparatus 130 may be implemented to include a GPU to process holographic information using numerical methods. The substrate alignment apparatus 150 may correspond to an apparatus implemented to perform a substrate alignment method according to the present disclosure.

In this case, the holographic optical apparatus 110 may be connected to the holographic signal processing apparatus 130, and the substrate alignment apparatus 150 may operate in conjunction with the holographic optical apparatus 110 and the holographic signal processing apparatus 130.

In one embodiment, the substrate alignment system 100 may include not only the holographic optical apparatus 110, but also an imaging optical apparatus for guiding purposes. In this case, the imaging optical apparatus may include a lighting unit, an imaging unit, and a camera unit, and may use all of visible wavelengths, infrared wavelengths, and ultraviolet wavelengths.

Meanwhile, in FIG. 1, each apparatus is depicted as an independent configuration, but such a depiction is not necessarily limiting, and the apparatuses may be selectively combined in implementation. In other words, implementation may be carried out such that one apparatus is included within another apparatus. Therefore, the substrate alignment system 100 according to the present disclosure may be implemented in various forms through different combinations of the respective apparatuses.

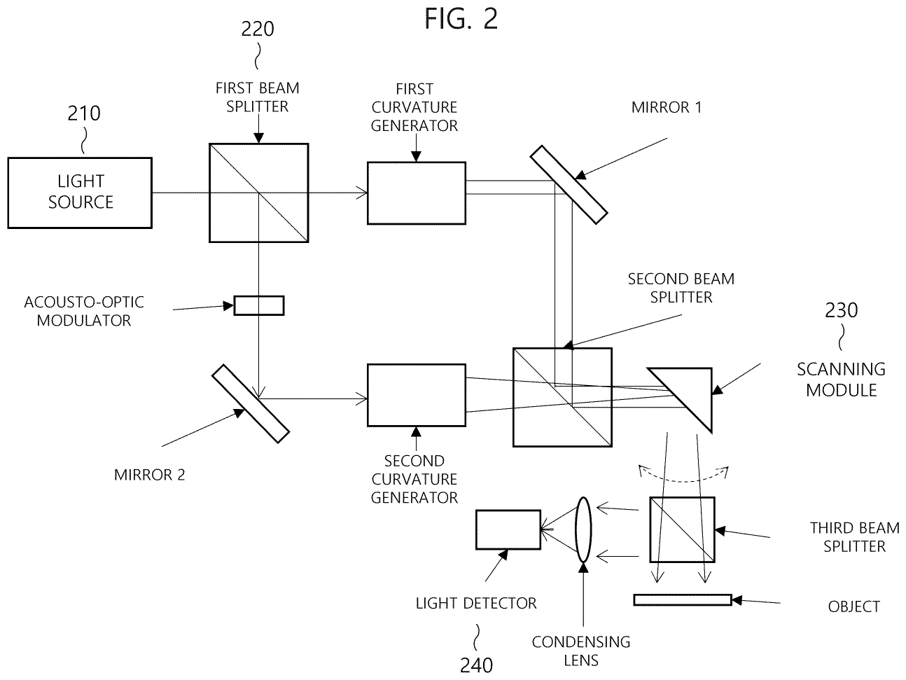

FIG. 2 is a drawing illustrating a holographic optical apparatus of FIG. 1.

Referring to FIG. 2, the holographic optical apparatus 110 may correspond to an optical apparatus based on scanning holography, and may include a light source unit 210 that uses any one of infrared, visible, and ultraviolet wavelengths, a scan beam generation unit 220 that branches light of a specific wavelength to generate a scan beam by interference, a scanning unit 230 that is capable of scanning an object, and a light detection unit 240 that converts light reflected or transmitted from the object into an electric signal. Here, the infrared wavelengths may correspond to NIR/IR wavelengths, and the light source unit 210 may selectively use light of not only the infrared wavelengths but also the visible or ultraviolet wavelengths.

For example, the object may correspond to a substrate, and the substrate may include an opaque substrate such as a wafer as well as a transparent substrate such as glass. The light source unit 210 may use an infrared (IR) light source for opaque substrates such as wafers, and may selectively use an infrared, visible, or ultraviolet light source for transparent substrates such as glass substrates.

In this case, the scan beam generation unit 220 may include a plurality of beam splitters to generate a scan beam, and may further include an optical modulator, a mirror, and the like. In addition, the holographic optical apparatus 110 may be implemented to obtain a complex hologram of the object.

In one embodiment, the light source unit 210 may include various types of light sources having coherence characteristics, such as lasers and LEDs. Here, coherence may be a measure of the extent to which interference can occur. That is, the light source unit 210 may be implemented by selectively applying a light source having coherence characteristics.

In one embodiment, the scan beam generation unit 220 may be configured to include one acousto-optic modulator, two beam splitters, a curvature generator, and a mirror. Specifically, a beam from the light source unit 210 using any one of infrared, visible, and ultraviolet wavelengths may be split into light of two paths while passing through a first beam splitter. Among the light split by the first beam splitter, a beam that is bent by reflection may be modulated to a specific frequency while passing through the acousto-optic modulator, and then reflected by Mirror 2 and transmitted to a second curvature generator. The transmitted light among the light split by the first beam splitter may be transmitted to a first curvature generator. The first curvature generator and the second curvature generator may generate an expanded beam having a curvature between negative curvature and positive curvature.

Specifically, the first curvature generator may be composed of Lens 1 and Lens 2, and the second curvature generator may be composed of Lens 3 and Lens 4. In this case, Lens 1 and Lens 2, Lens 3, and Lens 4 may be composed of lenses having different focal lengths, and the curvature of a beam may be adjusted by adjusting spacing between lenses. Light passing through the first curvature generator may be reflected by Mirror 1 and then transmitted to the second beam splitter. In the second beam splitter, light of a specific curvature generated by the first curvature generator and light of a specific curvature generated by the second curvature generator may be combined to form a scan beam having an interference pattern of Fresnel ring pattern. The Fresnel ring pattern may vary depending on the curvature of the beam generated by the first curvature generator and the curvature of the beam generated by the second curvature generator.

The scan beam of the Fresnel ring pattern generated by the second beam splitter may scan an object through a scanning module (or scanning unit) 230. The scanning module 230 may be composed of two scanners for scanning two axes of X and Y, and each scanner may include a calibrated scanner, a polygon scanner, a resonant scanner, and a spatial light modulator (DMD).

Thereafter, the scan beam of the Fresnel ring pattern scans the object, and light transmitted through the object or reflected from the object may be converted into the form of an electrical signal through the light detection unit 240. The light detection unit 240 may be configured to include a separate light collector to increase light collection efficiency, and may include various light detection means such as a photodiode and a PMT.

As a result, the holographic optical apparatus 110 may capture a hologram of an object present on an objective plate. In one embodiment, the holographic optical apparatus 110 may generate a complex hologram as a result of the capture.

More specifically, the holographic optical apparatus 110 may detect a beam transmitted from the object in addition to detecting a beam reflected or fluoresced from the object. In this case, an objective surface is preferably formed of glass, or a portion corresponding to the object may preferably be open.

In addition, the captured hologram may be expressed by the following Equations 1 to 5.

$${i}_{H}^{1} ( x , y ) = \int O ( {x}_{0} , {y}_{0} ; z ) ⊗ exp [ j \frac{π}{λ z} ( {x}_{0}^{2} + {y}_{0}^{2} ) ] dz \qquad [ Equation 1 ]$$

Here, O(x₀,y₀;z) refers to a three-dimensional image of the object, represented as a three-dimensional distribution of reflectance of the object, and ⊗ denotes a convolution operation. Also, (x, y) indicates a scan position of a scan beam determined by a scanning means, and z corresponds to a depth position of the object, representing a distance from a focal point of a spherical wave to the object.

$${i}_{H}^{2} ( x , y ) = \int O ( {x}_{0} , {y}_{0} ; z ) ⊗ exp [ j \frac{π d}{λ ( d + z ) z} ( {x}_{0}^{2} + {y}_{0}^{2} ) ] dz \qquad [ Equation 2 ]$$

Here, d denotes a distance between a focal point of a first spherical wave and a focal point of a second spherical wave. In the hologram, distortion due to reduction and magnification may be corrected by adjusting the distance d. One way to adjust d is to change the position and focal length of a lens according to the imaging laws of lenses.

$${i}_{H}^{3} ( x , y ) = \int O ( {x}_{0} , {y}_{0} ; z ) ⊗ exp [ j \frac{π d}{λ ( {z}^{2} - \frac{{d}^{2}}{4} )} ( {x}_{0}^{2} + {y}_{0}^{2} ) ] dz \qquad [ Equation 3 ]$$

Here, M_{img} is a reduction or magnification ratio of an image by a first lens when imaging a pattern of a surface of a polarization-sensitive lens (geometric phase lens) onto a surface of an object area, Z_{img} is a distance from a focal point position of the second spherical wave to the object, and 2M²_{img}f_{gp} is a distance between the focal points of the adjusted first and second spherical waves.

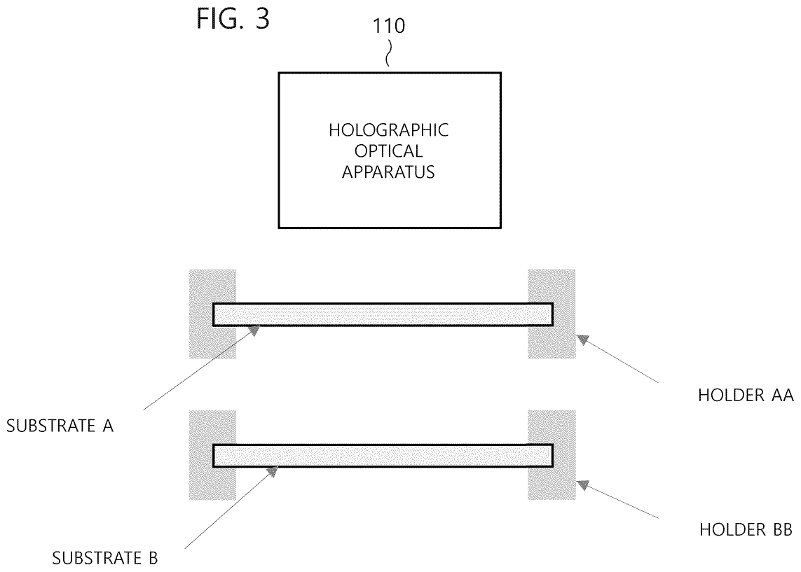

FIG. 3 is a drawing illustrating an arrangement structure of substrates at different positions according to the present disclosure.

Referring to FIG. 3, the substrate alignment apparatus 150 may be disposed below the holographic optical apparatus 110. The substrate alignment apparatus 150 may include a sample fixing unit for supporting substrates at different positions. In this case, the substrates at the different positions may include substrates at different positions and chips, and may also include chips and chips at different positions, as needed. In addition, it may, of course, be applicable not only to substrates and chips, but also to various articles that are formed in a planar structure and require alignment for bonding therebetween.

Here, for convenience, one of the two substrates is referred to as Substrate A and the other substrate is referred to as Substrate B. In addition, a sample fixing unit that fixes Substrate A is referred to as Holder AA, and a sample fixing unit that fixes Substrate B is referred to as Holder BB.

In FIG. 3, the substrate alignment apparatus 150 may fix Substrate A using Holder AA and fix Substrate B using Holder BB. The substrate alignment apparatus 150 may move the Holder AA and Holder BB to initial positions using a sample transfer unit. Here, the initial positions may refer to initial positions in the design, and a correction value may be applied, as needed. In this case, the substrate alignment apparatus 150 may position Substrate A and Substrate B as close as possible in a height direction through the sample fixing unit.

Meanwhile, there may be one or more alignment marks at specific positions on Substrate A and Substrate B to identify the positions of Substrate A and Substrate B. In addition, the alignment marks may be present on upper surfaces (top surfaces) or lower surfaces (bottom surfaces) of Substrate A and Substrate B.

When Substrate A and Substrate B are moved to the initial positions thereof by the substrate alignment apparatus 150, the holographic optical apparatus 110 may be also moved to an initial position thereof. Here, the initial positions may refer to initial positions in the design, and a correction value may be applied, as needed.

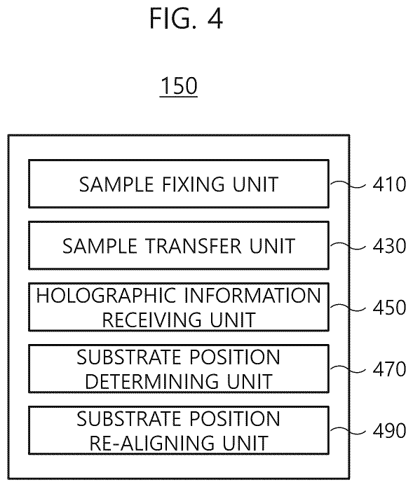

FIG. 4 is a drawing illustrating a functional configuration of the substrate alignment apparatus of FIG. 1.

Referring to FIG. 4, the substrate alignment apparatus 150 may include a sample fixing unit 410, a sample transfer unit 430, a holographic information receiving unit 450, a substrate position determining unit 470, a substrate position re-aligning unit 490, and a control unit (not shown in FIG. 4).

The sample fixing unit 410 may include a plurality of holders implemented to support substrates at different positions by fixing each of the substrates at both ends thereof. That is, the sample fixing unit 410 may fix the substrates at the different positions by applying a mechanical method through the plurality of holders. In this case, the substrates at the different positions may include substrates at different positions and chips, or chips and chips at different positions. In addition, the sample fixing unit 410 may be implemented in a structure that allows light to pass through a central portion or a specific portion having an alignment marker of the substrate.

In one embodiment, to prevent shaking or positional change of a sample during sample transport, the sample fixing unit 410 may fix the substrates at the different positions by applying a vacuum fixing method in addition to a mechanical method.

In one embodiment, the sample fixing unit 410 may be implemented in a structure in which a plurality of holders are arranged vertically side by side, so that the substrates are arranged vertically side by side.

The sample transfer unit 430 may move the substrates at the different positions, which are supported by the plurality of holders, to a specific position. To this end, the sample transfer unit 430 may be implemented to include a driving unit capable of moving a substrate along the X, Y, and Z axes and a rotating unit capable of rotating a substrate in the 0 direction.

The holographic information receiving unit 450 may receive holographic information about the substrates at the different positions from the holographic optical apparatus 110. To this end, the holographic information receiving unit 450 may operate in conjunction with the holographic optical apparatus 110. That is, when Substrate A and Substrate B of FIG. 3 are transferred to the initial positions, holographic information about the alignment marks of Substrates A and B may be obtained through the holographic optical apparatus 110.

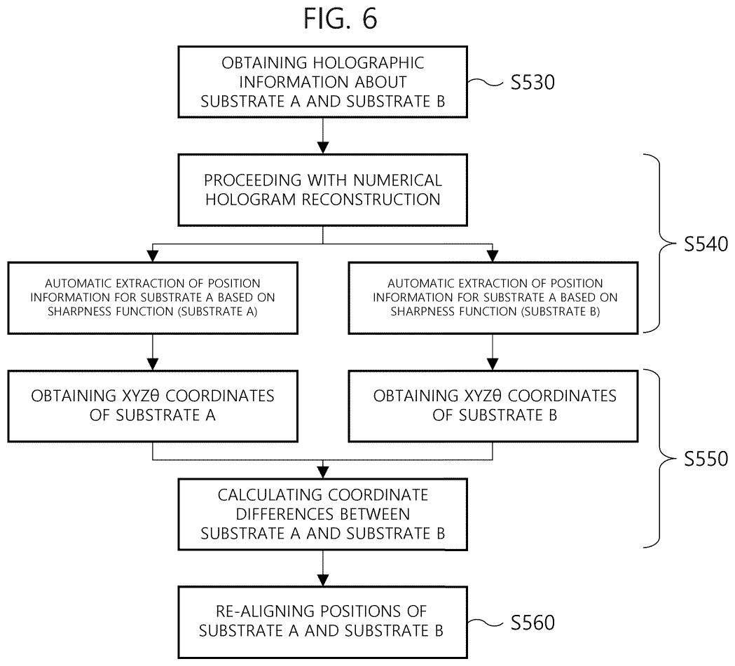

In one embodiment, the holographic information receiving unit 450 may obtain single integrated holographic information about at least one alignment mark displayed on an upper or lower surface of each of the substrates at the different positions. Instead of mechanically moving the holographic optical apparatus 110 in the height direction to obtain the holographic information at multiple heights, the holographic information receiving unit 450 may obtain the single integrated holographic information about Substrate A and Substrate B of FIG. 3. This will be described in more detail in FIG. 6.

The substrate position determining unit 470 may determine position information for the substrates at the different positions by analyzing the holographic information through the holographic signal processing apparatus 130. In one embodiment, the substrate position determining unit 470 may reconstruct the alignment marks of the respective substrates at the different positions based on the single integrated holographic information to generate independent reconstructed images for the alignment marks of the respective substrates. In one embodiment, the substrate position determining unit 470 may determine position coordinates for the alignment mark of each of the substrates at the different positions based on the respective reconstructed images. This will be described in more detail in FIG. 6.

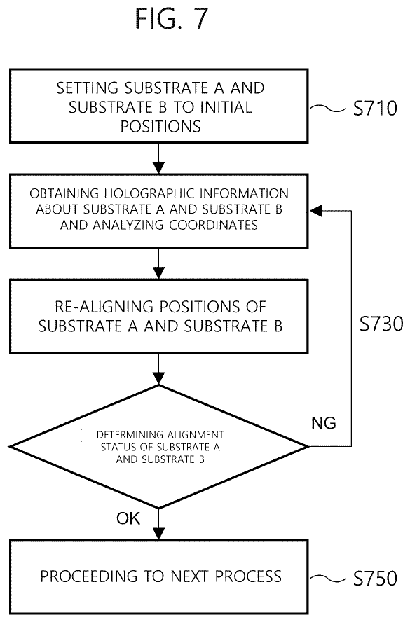

The substrate position re-aligning unit 490 may re-align the substrates at the different positions using position information derived through analysis of the holographic information. In one embodiment, the substrate position re-aligning unit 490 may calculate a difference between position coordinates for each of the alignment marks and re-align the substrates at the different positions based on the difference. That is, the substrate position re-aligning unit 490 may align the positions of the substrates at the different positions by analyzing the differences in X, Y, Z, and θ values of the substrates at the different positions and compensating for the relative differences. This will be described in more detail in FIG. 7.

The control unit (not shown in FIG. 4) controls the overall operation of the substrate alignment apparatus 150 and may manage a control flow or data flow among the sample fixing unit 410, the sample transfer unit 430, the holographic information receiving unit 450, the substrate position determining unit 470, and the substrate position re-aligning unit 490.

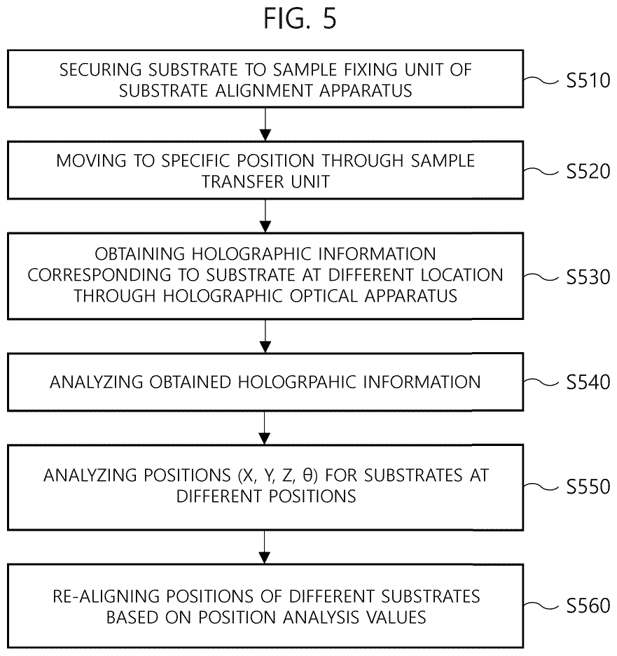

FIG. 5 is a flowchart illustrating a substrate alignment method according to the present disclosure.

Referring to FIG. 5, the substrate alignment apparatus 150 may secure substrates at different positions through the sample fixing unit 410 (S510).

Thereafter, the substrate alignment apparatus 150 may move the substrates to a specific position through the sample transfer unit 430 (S520). In this case, the specific position may correspond to an initial position in the design and may be changed by applying a correction value, as needed.

Thereafter, the substrate alignment apparatus 150 may obtain holographic information corresponding to the different positions of the substrate from the holographic optical apparatus 110 (S530). The substrate alignment apparatus 150 may analyze the obtained holographic information (S540) and determine position information (X, Y, Z, θ) for the substrates at the different positions (S550).

Thereafter, the substrate alignment apparatus 150 may re-align the positions of the different substrates using position analysis values (S560).

FIG. 6 is a flowchart illustrating one embodiment of a substrate alignment process according to the present disclosure.

Referring to FIG. 6, the substrate alignment apparatus 150 may obtain holographic information about Substrate A and Substrate B of FIG. 3 from the holographic optical apparatus 110 (S530), and may re-align the positions of the substrates using the obtained holographic information (S560). In this case, the holographic optical apparatus 110 may collect holographic information about Substrate B positioned below Substrate A together since light from a light source unit may pass through an opaque substrate when infrared wavelengths are used. That is, the holographic optical apparatus 110 may observe alignment marks regardless of whether the alignment marks are located on upper or lower surfaces of Substrate A and Substrate B.

In addition, since light from the light source unit is not able to pass through an opaque substrate when visible or ultraviolet wavelengths are used, the holographic optical apparatus 110 may simultaneously observe the alignment marks of the substrates and collect holographic information by using a transparent substrate such as a glass substrate.

In addition, by processing the holographic information using a numerical processing method through the holographic signal processing apparatus 130, the substrate alignment apparatus 150 may obtain an image in which the alignment mark of Substrate A of FIG. 3 is clearly reconstructed and an image in which the alignment mark of Substrate B is clearly reconstructed, respectively. As a result, the substrate alignment apparatus 150 may collect the clear images of the alignment marks of Substrate A and Substrate B, which are positioned at different heights, from single holographic information.

Meanwhile, the formula for reconstructing the hologram obtained above may be expressed as the following Equation 6.

$${i}_{H}^{4} ( x , y ) = \int O ( {x}_{0} , {y}_{0} ; z ) ⊗ exp [ j \frac{2 π {f}_{gp}}{λ ( 2 {f}_{gp} + z ) z} ( {x}_{0}^{2} + {y}_{0}^{2} ) ] dz \qquad [ Equation 4 ]$$

Here, I₀ represents light reflected from the object or transmitted through the object, and

$${i}_{H}^{5} ( x , y ) = \int O ( {x}_{0} , {y}_{0} ; z ) ⊗ exp [ j \frac{2 π {M}_{img}^{2} {f}_{gp}}{λ ( 2 {M}_{img}^{2} {f}_{gp} + {z}_{img} ) {z}_{img}} ( {M}_{img}^{2} {x}_{0}^{2} + {M}_{img}^{2} {y}_{0}^{2} ) ] dz \qquad [ Equation 5 ]$$

represents a beam pattern formed by the scan generation unit 220 of the holographic optical apparatus 110.

In the numerical processing method mentioned above, an automatic height position information extraction algorithm based on a sharpness function may be applied to automatically and clearly reconstruct the alignment marks of Substrate A and Substrate B. Here, the automatic height position information extraction algorithm based on a Sharpness function may be applied to each of the alignment marks of Substrate A and Substrate B, and a height value corresponding to the optimal algorithm result value may be determined as a reconstruction position of each substrate (S540).

In addition, the Sharpness function may include various sharpness functions, such as an algorithm using Tamura coefficients, an algorithm using frequency domain data, an algorithm using intensity information of each pixel, and an algorithm using information from adjacent pixels together.

The substrate alignment apparatus 150 may obtain XYZθ coordinates of each alignment mark by analyzing the clearly reconstructed alignment mark image of Substrate A and the alignment mark image of Substrate B (S550). The substrate alignment apparatus 150 may compare and analyze the obtained XYZθ coordinates of the alignment mark of Substrate A and the XYZθ coordinates of the alignment mark of Substrate B to calculate a coordinate difference between the two alignment marks.

Thereafter, the substrate alignment apparatus 150 may re-align the positions of Substrate A and Substrate B based on a calculated XYZθ difference (S560).

FIG. 7 is a flowchart illustrating one embodiment of an overall process including a substrate alignment process according to the present disclosure.

Referring to FIG. 7, the substrate alignment apparatus 150 may move Substrate A and Substrate B of FIG. 3 to initial positions thereof (S710).

In the next step, the substrate alignment apparatus 150 may obtain holographic information about Substrate A and Substrate B from the holographic optical apparatus 110 and then analyze coordinates. In addition, the substrate alignment apparatus 150 may re-align the positions of Substrate A and Substrate B, and determine an alignment status of Substrate A and Substrate B based on a re-alignment result (S750).

If the alignment status of the substrates does not meet a preset condition, the substrate alignment apparatus 150 may perform a re-alignment operation by re-collecting and analyzing holograms of the substrates. That is, the substrate alignment apparatus 150 may repeatedly perform an alignment operation on the substrates, so that the substrates are ultimately aligned in accordance with a desired condition.

For example, if the alignment status of Substrate A and Substrate B is determined to be worse than a reference value, the process of acquiring a hologram may be performed again, and by repeatedly performing the process, an alignment status below the reference value may be achieved. Accordingly, if the alignment status of the substrates satisfies the condition, the next process may be performed on the substrates (S750).

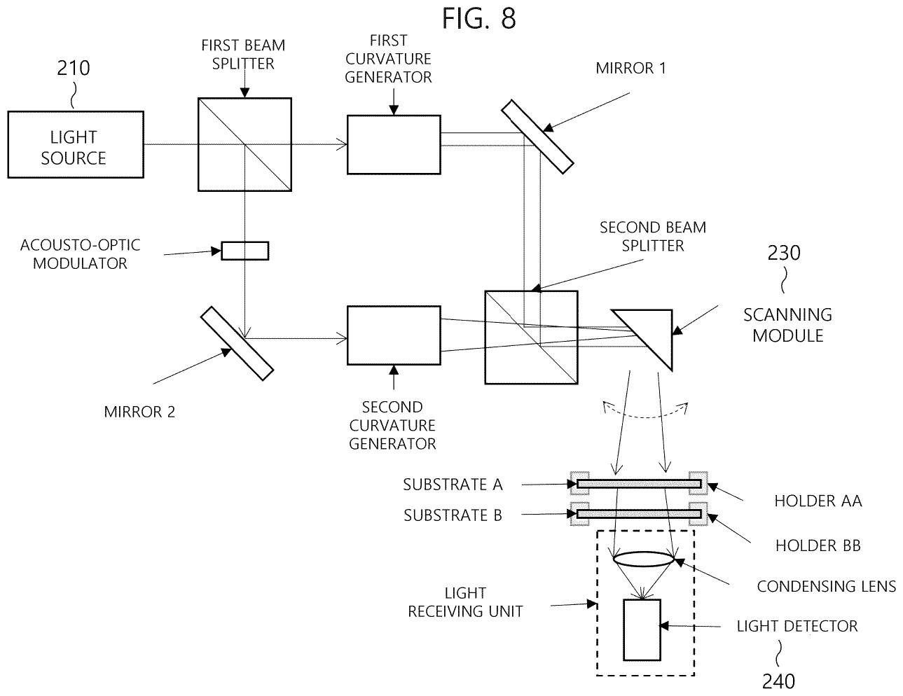

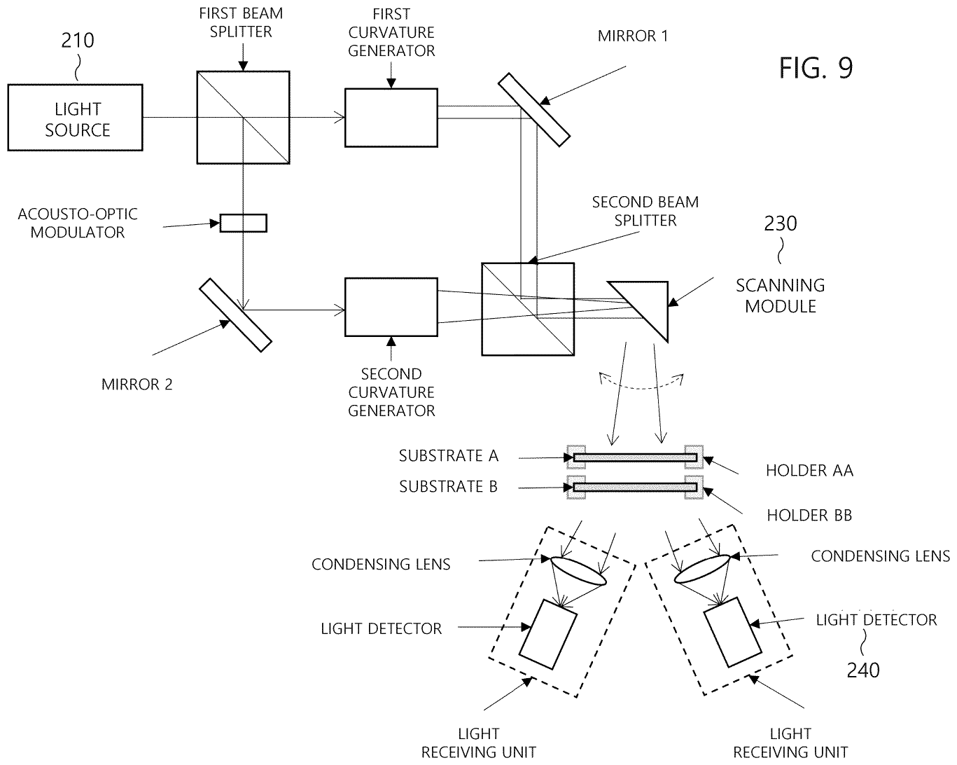

FIGS. 8 and 9 are drawings illustrating various embodiments of a transmissive structure of a holographic optical apparatus according to the present disclosure.

Referring to FIG. 8, a structure is illustrated in which the light source unit 210 of the holographic optical apparatus 110 is positioned above Substrate A and the light receiving unit of the holographic optical apparatus 110 is positioned below Substrate B. In more detail, the light source unit 210 of the scanning holography-based holographic optical apparatus 110 may be positioned above Substrate A, and the light detection unit 240 may be positioned below Substrate B. In a case where the light source unit 210 of the scanning holography-based holographic optical apparatus 110 uses infrared wavelengths, when scanning opaque Substrate A and Substrate B, which are objects, using the scanning unit 230, the scanning light may pass through Substrate A and Substrate B, and the light transmitted therethrough may be converted into an electric signal through the light detection unit 240. If transparent Substrates A and B are to be scanned, the light source unit 210 may selectively use any one of infrared, visible, and ultraviolet wavelengths. As such, the transmissive structure may correspond to a structure in which holographic information about Substrate A and Substrate B is obtained using light transmitted through the substrates.

As shown in FIG. 8, in the case of the transmissive structure, the light source unit 210 of the holographic optical apparatus 110 and the light receiving unit of the holographic optical apparatus 110 may be arranged coaxially, so that light emitted from the light source unit 210 can pass through a substrate in a straight line to obtain holographic information about the substrate through the light receiving unit. In addition, the light receiving unit may include the arrangement of a separate condensing optical system to improve light collection efficiency.

Referring to FIG. 9, a structure is illustrated in which the light source unit 210 of the holographic optical apparatus 110 and the light receiving unit of the holographic optical apparatus 110 arranged off-axis in a transmissive structure. That is, through the corresponding structure, it is possible to obtain holographic information optimized for the phenomenon in which light emitted from the light source unit 210 is refracted or diffracted while passing through a substrate. In addition, the corresponding structure may include arrangement of a separate condensing optical system to improve light collection efficiency, and may include arrangement of a single light receiving unit or arrangement of a plurality of light receiving units.

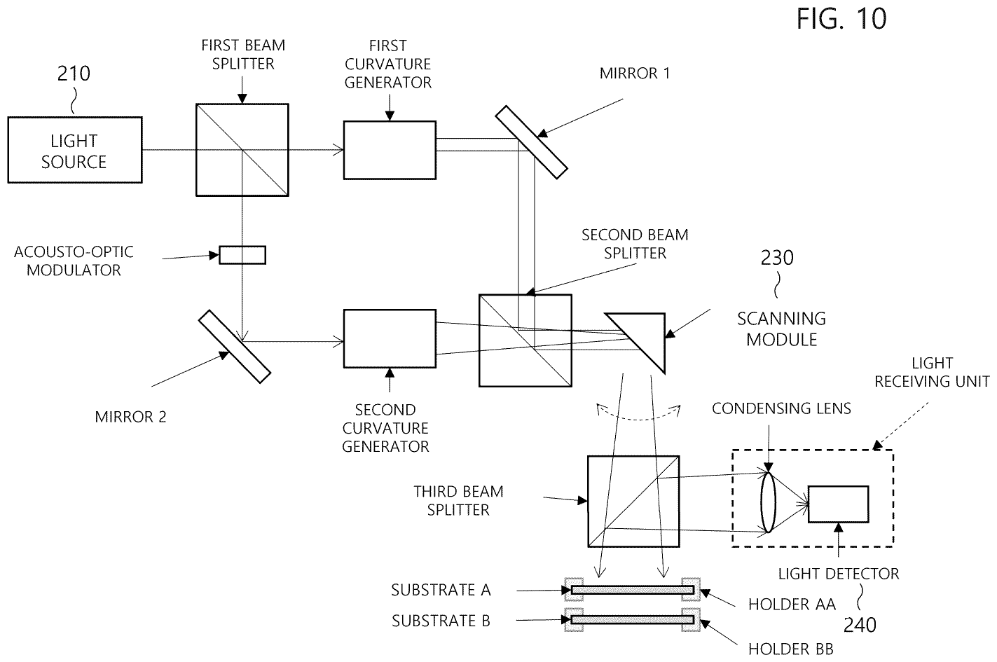

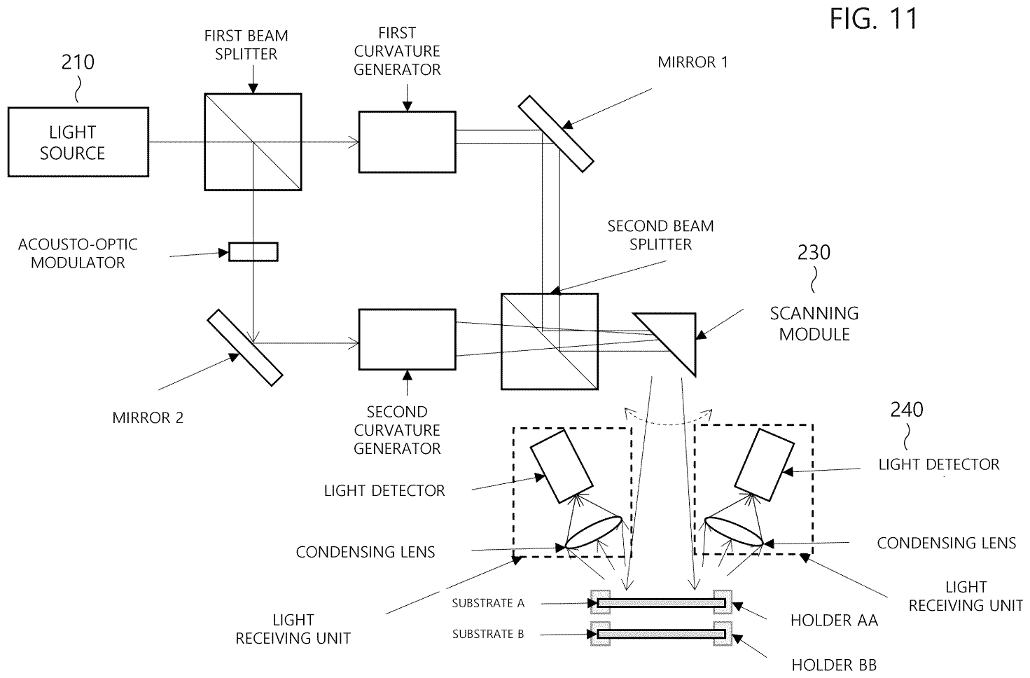

FIGS. 10 and 11 are drawings illustrating various embodiments of a reflective structure of a holographic optical apparatus according to the present disclosure.

Referring to FIG. 10, a structure is illustrated in which both the light source unit 210 and the light receiving unit of the holographic optical apparatus 110 are positioned above Substrate A. In more detail, the light source unit 210 and the light detection unit 240 of the scanning holography-based holographic optical apparatus 110 are positioned above Substrate A, and a beam splitter may be additionally disposed, unlike the transmissive type, to detect reflected light after scanning an object using the scanning unit 230. Substrates A and B are opaque, but because light of infrared wavelengths is used in the light source unit 210 of the holographic optical apparatus 110, light transmitted through Substrate A is reflected by Substrate B and holographic information about the object may be obtained using the light reflected from Substrates A and B, and this structure may correspond to a reflective structure. When using transparent Substrates A and B, any one of infrared, visible, and ultraviolet wavelengths may be selectively used in the light source unit 210.

That is, the reflective structure may include a structure such as a mirror or reflector positioned below an object to reflect light that has passed through the object, and may indicate that a mirror or reflector is positioned below Substrate B in FIG. 10. In addition, the corresponding structure may include a plurality of components capable of functioning as mirrors to form a structure in which transmitted light is reflected.

In addition, in the case of the reflective structure, as shown in FIG. 10, the light source unit 210 of the holographic optical apparatus 110 and the light receiving unit of the holographic optical apparatus 110 may be arranged coaxially, so that light emitted from the light source unit 210 is reflected in a straight line from a substrate and holographic information about the substrate is obtained through the light receiving unit.

Referring to FIG. 11, a structure is illustrated in which the light source unit 210 of the holographic optical apparatus 110 and the light receiving unit of the holographic optical apparatus 110 are arranged off-axis, so that when light emitted from the light source unit 210 is reflected from a substrate, holographic information optimized for diffusely reflected light or light reflected at a specific angle may be obtained. In addition, the structure may include arrangement of a separate condensing optical system to increase light collection efficiency, and may include arrangement of a single light receiving unit or arrangement of a plurality of light receiving units.

Although the present disclosure has been described above with reference to preferred embodiments thereof, it will be understood by those skilled in the art that various modifications and changes may be made to the present disclosure without departing from the spirit and scope of the present disclosure as set forth in the claims below.

### DESCRIPTION OF REFERENCE NUMERALS

100: substrate alignment system
110: holographic optical apparatus
130: holographic signal processing apparatus
150: substrate alignment apparatus
210: light source unit
220: scan beam generation unit
230: scanning unit
240: light detection unit
410: sample fixing unit
430: sample transfer unit
450: holographic information receiving unit
470: substrate position determining unit
490: substrate position re-aligning unit

1. A scanning holography-based substrate alignment apparatus comprising:
a sample fixing unit comprising a plurality of holders configured to support substrates at different positions by fixing each of the substrates at both ends thereof, each of the substrates comprising a substrate and a chip;
a sample transfer unit configured to move the substrates at the different positions supported by the plurality of holders to a specific position;
a holographic information receiving unit configured to receive holographic information about the substrates at the different positions from a holographic optical apparatus;
a substrate position determination unit configured to analyze the holographic information through a holographic signal processing apparatus to determine position information for the substrates at the different positions; and
a substrate position re-aligning unit configured to re-align the substrates at the different positions using the position information.

2. The apparatus of claim 1,
wherein the holographic optical apparatus comprises:
a light source unit using any one of infrared, visible, and ultraviolet wavelengths;
a scan beam generation unit configured to branch light of a specific wavelength to generate a scan beam through interference;
a scanning unit capable of scanning an object; and
a light detection unit configured to convert light reflected or transmitted from the object into an electrical signal,
wherein the holographic optical apparatus is implemented to obtain a complex hologram of the object.

3. The apparatus of claim 1, wherein the sample fixing unit is implemented in a structure in which the plurality of holders are arranged vertically side by side, so that the substrates are arranged vertically side by side.

4. The apparatus of claim 1, wherein the holographic information receiving unit obtains single integrated holographic information about at least one alignment mark displayed on an upper or lower surface of each of the substrates at the different positions.

5. The apparatus of claim 4, wherein the substrate position determining unit reconstructs alignment marks of the respective substrates at the different positions based on the single integrated holographic information to generate independent reconstructed images for the alignment marks of the respective substrates.

6. The apparatus of claim 5, wherein the substrate position determining unit determines position coordinates for the alignment marks of the respective substrates at the different positions based on the respective reconstructed images.

7. The apparatus of claim 6, wherein the substrate position re-aligning unit calculates a difference between the position coordinates of each of the alignment marks and re-aligns the substrates at the different positions based on the difference.

8. A scanning holography-based substrate alignment method performed by a substrate alignment apparatus, the method comprising:
supporting, through a sample fixing member, substrates at different positions by fixing each of the substrates at both ends thereof using a plurality of holders, wherein each substrate comprising a substrate and a chip;
moving, through the sample transfer unit, the substrates at the different positions supported by the plurality of holders to a specific position;
receiving, through a holographic information receiving unit, holographic information about the substrates at the different positions from a holographic optical apparatus;
determining, through a substrate position determining unit, position information for the substrates at the different positions by analyzing the holographic information through a holographic signal processing apparatus; and
re-aligning the substrates at the different positions using the position information through a substrate position re-aligning unit.
